(19) United States
(12) Patent Application Publication
(10) Pub. No.: US 2026/0304708 A1
(43) Pub. Date: Oct. 1, 2026

(54) SEPARATION FILMS WITH ATTACHMENT MECHANISMS

(71) Applicant: 3M INNOVATIVE PROPERTIES COMPANY, St. Paul, MN (US)

(72) Inventors: Ali Evren Ozcam, St. Paul, MN (US); Derek J. Dehn, Maplewood, MN (US); Kiran P. Khanijow, Austin, TX (US); Samuel D. Van Alstyne, St. Paul, MN (US); Abhay R. Joshi, Oakdale, MN (US); Sebastian Goris, Inver Grove Heights, MN (US); Timothy J. Lindquist, Woodbury, MN (US); Robert M. Biegler, Woodbury, MN (US); Justin L. Lalor, St. Paul, MN (US); Gerardo Mazzei Capote, St. Paul, MN (US); Mary E. Johansen, Woodbury, MN (US)

(21) Appl. No.: 19/474,893

(22) PCT Filed: May 6, 2024
(86) PCT No.: PCT/US2024/027946

§ 371 Date: Oct. 13, 2025

Related U.S. Application Data
(60) Provisional application No. 63/500,695, filed on May 8, 2023.
(60) Provisional application No. 63/640,284, filed on Apr. 30, 2024.

(51) Int. Cl. H05K 7/20

(52) U.S. Cl. CPC H05K 7/20718

(57) ABSTRACT

A film module for use in a data center includes a frame with a first portion of the frame having a transparent film. A second portion of the frame has an open space without the film. The first portion is configured to separate a hot aisle from a cold aisle in a data center or other facility, and the second portion is configured to provide cold air from the cold aisle through the electronic equipment to be cooled in the data center and into the hot aisle. The film module can also be used in other facilities such as clean rooms, remediation sites, and greenhouses to create an air barrier between sections of the facilities. The air barrier can prevent or hinder air flow between the sections.

### BACKGROUND

Data centers are large energy intensive buildings designed to house row upon row of servers. These servers are commonly used by large companies to provide web and cloud-based services. These data centers are designed to provide the optimal environment for the servers while trying to minimize the environmental impact. One way that newer data centers operate is to flow cool air from an aisle way through the server to take away heat into a hot aisle. These aisle ways are commonly made using transparent polycarbonate sheets. The polycarbonate sheets function to separate and isolate the hot and cold air. The polycarbonate sheets are clear because on occasion a person will need to inspect or access the servers to perform maintenance. With clear aisle dividers a person can visually monitor the servers outside of the hot aisle to minimize risk from exposure to the hot air. The polycarbonate sheets currently used are very thick and not the most environmentally friendly solution because polycarbonate has a high CO2 footprint compared to other polymers. A greener solution is desired for future designs of aisle dividers in data centers or other facilities.

### SUMMARY

A film module for use in a data center includes a frame with a first portion of the frame having a transparent film. A second portion of the frame has an open space without the film. The first portion is configured to separate a hot aisle from a cold aisle in a data center, and the second portion is configured to provide cold air from the cold aisle through the electronic equipment to be cooled in the data center and into the hot aisle.

The film module can also be used in other facilities such as clean rooms, remediation sites, and greenhouses.

### BRIEF DESCRIPTION OF THE DRAWINGS

FIG. 1 is a perspective view of a separation film module.

FIG. 2 is a perspective view of separation film modules configured to separate hot and cold aisles in a data center or other facility.

FIG. 3 is a side view illustrating separation of the hot and cold aisles in a data center or other facility.

FIG. 4A is a side view illustrating fasteners used to secure a separation film to a surface of a frame.

FIG. 4B is a side view illustrating two-sided adhesive used to secure a separation film to a surface of a frame.

FIG. 4C is a side sectional view illustrating edge clips used to secure a separation film to a frame.

FIG. 4D is a side view illustrating reclosable fasteners used to secure a separation film to a surface of a frame.

FIG. 4E is a perspective view of a round gasket to secure a separation film to a frame.

FIG. 4F is a perspective view of a round gasket with a flat cover plate to secure a separation film to a frame.

FIG. 4G is a perspective view of a cover plate with a ridge to secure a separation film to a frame.

FIG. 5A is a perspective view of a honeycomb structure for a separation film.

FIG. 5B is a perspective view of a corrugated structure for a separation film.

FIG. 5C is a perspective view of a thermoformed structure for a separation film.

FIG. 6 is a side view of a striped structure for a separation film.

FIG. 7 is a perspective view of a machine pleated structure for a separation film.

FIG. 8 is a perspective view of a hand pleated structure for a separation film.

FIG. 9 is a top view diagram, looking down at a building or other structure, to illustrate use of a separation film in other buildings or structures.

### DETAILED DESCRIPTION

Embodiments of this invention include an environmentally friendly, transparent, data center hot aisle and cold aisle separation or divider film. The film provides the separation of the hot and cold air and can be transparent to provide the visual safety requirement in data centers. The film is significantly thinner than the polycarbonate sheets currently used in data centers, and the film can be made of a polymer that has a lower CO2 footprint than polycarbonate thereby making it a greener solution. The film can optionally have tear resistant properties and also optionally have a noise or sound absorbing function to prevent it from functioning similar to a drum when mounted. The film can optionally have a structure that promotes better insulation from one major surface of the film to the other opposing surface. A tint coating, ultraviolet (UV) coating, and thermal and antioxidant stabilizer can optionally be added to the film to provide color, UV blocking, and required or desired service life. The film can optionally be multilayered, co-extruded, or both multilayered and co-extruded.

Other embodiments can include one or more of the following features.
1. Films to support fastening and sealing solutions: Mechanical fasteners which also tension the film and magnetic fasteners as another reclosable option.
2. Heat shrinking films to tension a separation film.
3. Film structures to provide a retractable, self-supporting, roof.
4. A folded film combined with a reclosable fastener for lower containment sealing to servers.
5. The use of film sheets, fasteners, and features for the construction of not just data centers but also clean rooms, construction sites, remediation containment, and green houses.
6. Incorporation of recycled polymer in the formation of separation films.

### Separation Films for Data Centers

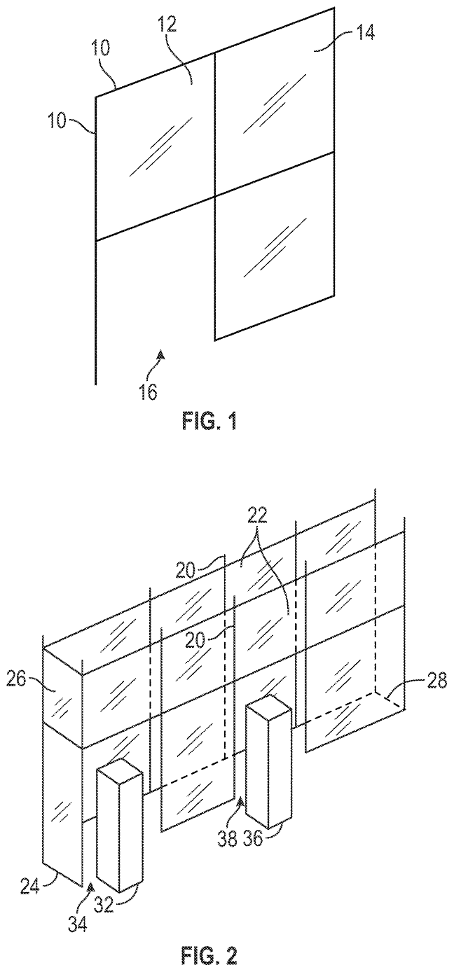

FIG. 1 is a perspective view of a separation film module. This module includes a frame 10 with a portion of the frame supporting a film having panels 12 and 14. Panels 12 and 14 are typically on a surface of the frame and can each have individual separation films or, alternatively, a continuous sheet of separation film can span multiple panels or portions of the frame. The film can be implemented with, for example, a monolithic transparent flexible film as shown in FIG. 1, or other films described below. The frame is arranged with an open space or portion 16 not having a film panel. In use, portion 16 is located adjacent a server or electronic equipment to be cooled from air flow from a cold aisle in a data center. Panels 12 and 14 are repeated and configured to maintain separation of hot and cold aisles in a data center. The frame can be implemented with, for example, extruded aluminum braces, or plastic pipes or rods having sufficient rigidity to hold the films in a required or desired configuration. The frame can optionally include one or more sub-frames, and the film can optionally be a framed film which is then secured to the frame.

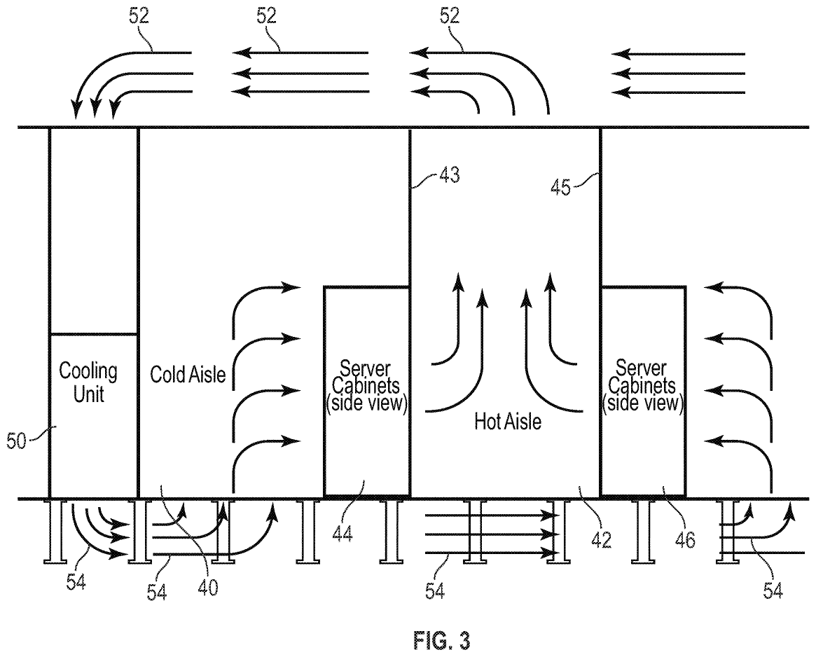

FIG. 2 is a perspective view of separation film modules configured to separate hot and cold aisles in a data center or other facility. The modules are held by a frame 20 securing films 22 along opposing sides and an optional film 26 on a first end 24. A second end 28, opposite first end 24, can optionally include the same or a similar configuration as first end 24. Films 22 can correspond with panel 14 repeated along both sides, and film 26 can correspond with panel 14 on first end 24. Films 22 and 26 can extend from the top of the frame to the bottom of the frame or in areas between the top and bottom of the frame.

The frame also includes an open space 34 (not containing a separation film), corresponding with portion 16 and providing for flow of cold air through a server or electronic equipment 32 and into the hot aisle. The frame includes another open space 38 (not containing a separation film), corresponding with portion 16 and providing for flow of cold air through a server or electronic equipment 36 and into the hot aisle. Servers or electronic equipment 32 and 36 are shown conceptually positioned at the open spaces. In use, servers or electronic equipment 32 and 36 would be about the same width as, or slightly narrower than, the open spaces to provide for efficient flow of cold air through them for cooling.

Thus, the films can be located on frame 20 in the locations not including a server or electronic equipment, and frame 20 can include open spaces or portions adjacent the servers or electronic equipment to be cooled. Frame 20 can be free-standing or optionally attached to the cabinets for the servers or other electronic equipment. First end 24 can optionally include a door to access the space between the opposing sides. The space between and within the opposing sides can correspond with, for example, a data center cold aisle as further described below.

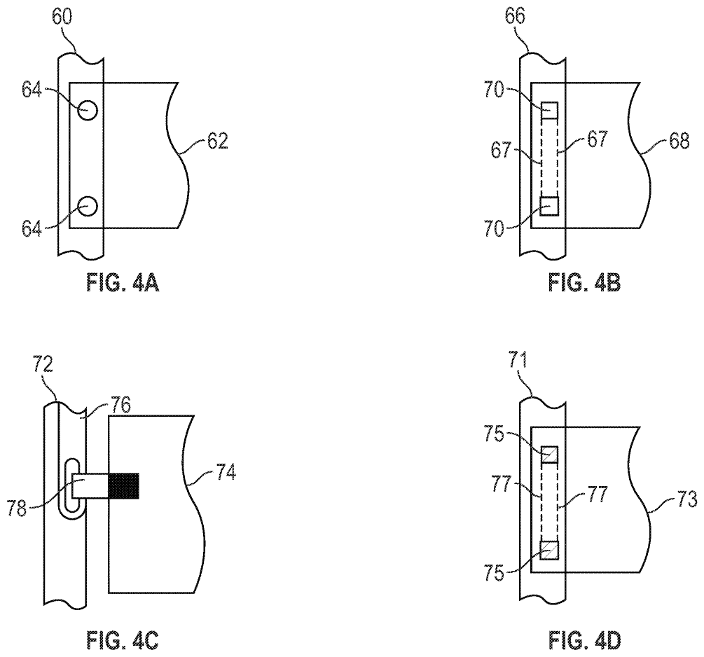

FIG. 3 is a side view illustrating separation of the hot and cold aisles using, for example, the configuration of films shown in FIG. 2. A cooling unit 50, such as a Computer Room Air Conditioner (CRAC), provides cold air to a cold aisle 40 via air flow path 54. The cold air passes through server cabinets 44 and 46 to cool servers or electronic equipment located within them. The cold air passing through server cabinets 44 and 46 becomes heated and enters a hot aisle 42 where the air returns to cooling unit 50 via air flow path 52. Cold aisle 40 is separated from hot aisle 42 using the configuration of film panels shown in FIG. 2, for example separation films 43 and 45, with server cabinets 44 and 46 located at open spaces corresponding with open spaces 34 and 38.

The flooring and ceiling panels in the configuration shown in FIG. 3 include vents or openings to provide for flow of cold air and hot air. In particular, the flooring panels include vents or openings below the cold aisle to provide for the cold air to enter the cold aisles via air flow path 54, and the ceiling panels include vents or openings above the hot aisle to provide for the hot air from the hot aisle to return to cooling unit 50 via air flow path 52. As shown, the flooring panels are used in a raised floor to provide for air flow beneath the flooring panels. To further isolate the cold and hot aisles, the flooring panels below the hot aisle are completely or substantially without vents or openings to provide for air flow path 54, and the ceiling panels above the cold aisle are completely or substantially without vents or openings to provide for air flow path 52. The frame for the configuration of film panels can extend, for example, completely or partially between the flooring panels and the ceiling panels to separate the cold aisles from the hot aisles. As an alternative to a raised floor, the separation films can be used in a data center or other facility having a slab floor.

### Attachment Mechanisms for Separation Films

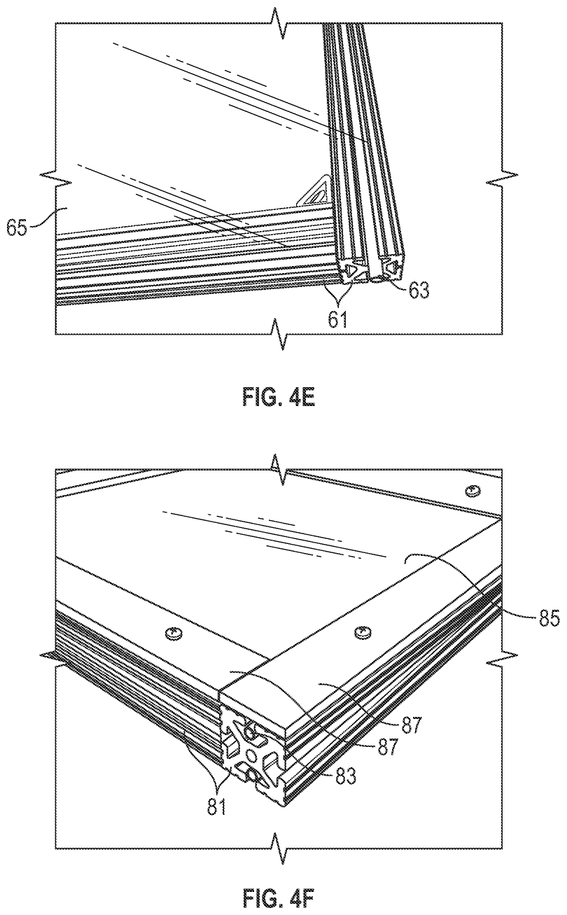

FIGS. 4A-4G illustrate options for securing a separation film to a frame.

FIG. 4A is a side view illustrating fasteners 64, such as screws with washers, used to secure a separation film 62 to a surface of a frame 60.

FIG. 4B is a side view illustrating two-sided adhesive 70 used to secure a separation film 68 to a surface of a frame 66. The adhesive 70 can be in discrete pieces around the perimeter as shown or continuous as represented by lines 67. Also, use of an adhesive can provide for a complete or partial air seal between the film and the frame. As an alternative to two-sided adhesive, a transfer tape can be used to secure the separation film to the frame. The following are exemplary implementations of tapes and adhesives for fasteners: VHB Architectural Panel Tape G11F from 3M Company; Double Coated Polyethylene Foam Tape 4492B from 3M Company; Double Coated Tape GPT-020F from 3M Company; and SCOTCH ATG Adhesive Transfer Tape 926 from 3M Company.

FIG. 4C is a side sectional view illustrating an edge clip 78 inserted into a slot 76 in a frame 72 and used to secure a separation film 74 to frame 72.

FIG. 4D is a side view illustrating reclosable fasteners 75 used to secure a separation film 73 to a surface of a frame 71. The reclosable fasteners 75 can be in discrete pieces around the perimeter as shown or continuous as represented by lines 77. One type of reclosable fasteners are magnetic fasteners applied with adhesive to the film, which can then magnetically attach the film to the support structure (e.g., frame) if that structure is magnetic. If the support structure is not magnetic, then an additional magnet can be applied to the structure to provide a magnet-to-magnet bond, for example when using non-magnetic support materials such as aluminum. The final product could be a frameless film that provides sufficient or adequate sealing properties. The following are exemplary implementations of reclosable fasteners: hook & loop-low profile fasteners (e.g., Hook Fastener SJ3506 and Hook Fastener SJ3507 both from 3M Company); hook & loop-standard fasteners (e.g., Hook Fastener SJ3571 and Hook Fastener SJ3572 both from 3M Company); DUAL LOCK Reclosable Fastener TB4570 Low Profile from 3M Company; and DUAL LOCK Reclosable Fastener TB3870 Standard from 3M Company.

FIG. 4E is a perspective view of a round gasket to secure a separation film to a frame. This round gasket includes a frame 61, a separation film 65, and a gasket 63 to secure separation film 65 to frame 61. FIG. 4F is a perspective view of a round gasket with a flat cover plate to secure a separation film to a frame. This round gasket includes a frame 81, a separation film 85, a gasket 83 to secure separation film 85 to frame 81, and a flat cover plate 87 capped over frame 81. Films 65 and 85 are secured to frames 61 and 81 via gaskets 63 and 83, respectively, for example with the films being held between the gaskets and frames, or with the films being wrapped around the gaskets.

FIG. 4G is a perspective view of a cover plate with a ridge to secure a separation film to a frame. As shown in FIG. 4G, a separation film 114 is secured to a frame 110 by being located and held between a cover plate 116 with a ridge 118 and frame 110. Film 114 is tensioned by ridge 118. The taller the ridge height the more the film is tensioned as the cap (cover) plate is secured to the frame with screws or other fasteners. An ⅛″ rib height made the film tight on 17″×17″ frames leaving a taut appearance even in the corners. The firmness of the film is substantially increased in this construction due to the tensioning effect, which changes the vibration properties of the film and can reduce sound or noise from the film.

This use of gaskets, as shown in FIGS. 4E-4F, could provide for a fast installation method of a separation film. These cap plates were shown to work well.

These ways of securing a separation film to a frame, or other ways, can be repeated along the frame as necessary or desired to provide the configuration of film panels.

### Options for Separation Films

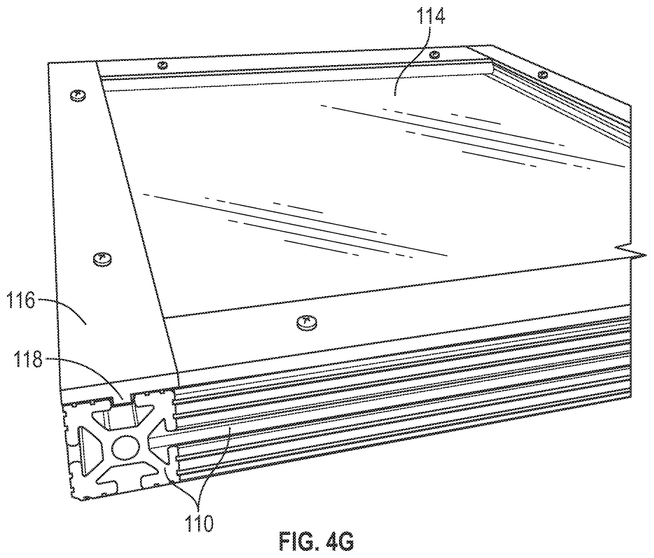

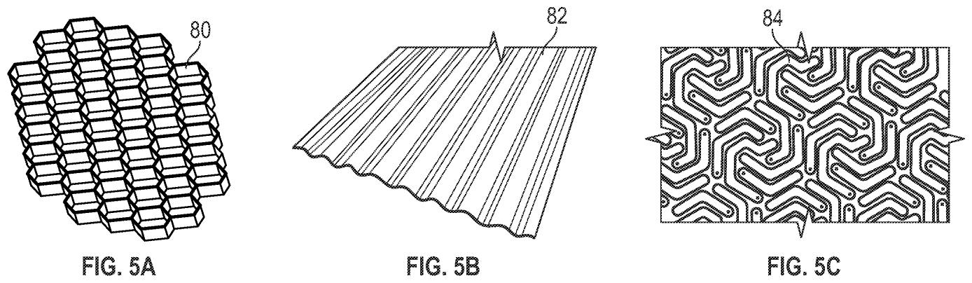

FIGS. 5A-5C and 6-8 illustrate options for the separation films aside from the film shown in FIG. 1. FIG. 5A is a perspective view of a honeycomb structure 80 for a separation film. Honeycomb films can include honeycomb laminates and a honeycomb structure for sound dampening. FIG. 5B is a perspective view of a corrugated structure 82 for a separation film. FIG. 5C is a perspective view of a thermoformed structure 84 for a separation film. FIG. 6 illustrates another option for a separation film and is a side view of a striped structure, which includes glass filled polymer composites having layers of high recycled content 90 alternating or interleaved with layers of transparent windows 92. The striped structure can optionally incorporate glass bubbles for insulation along with structures to trap air.

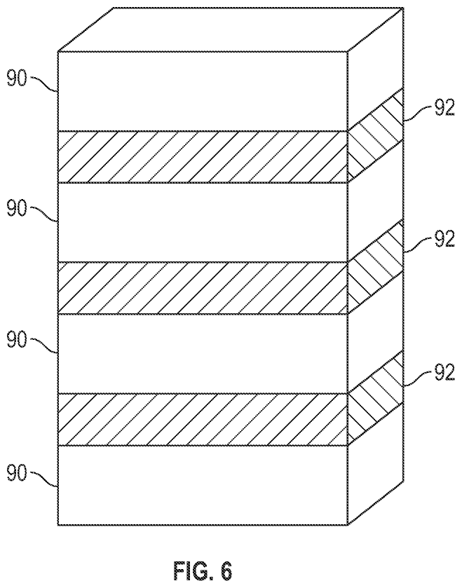

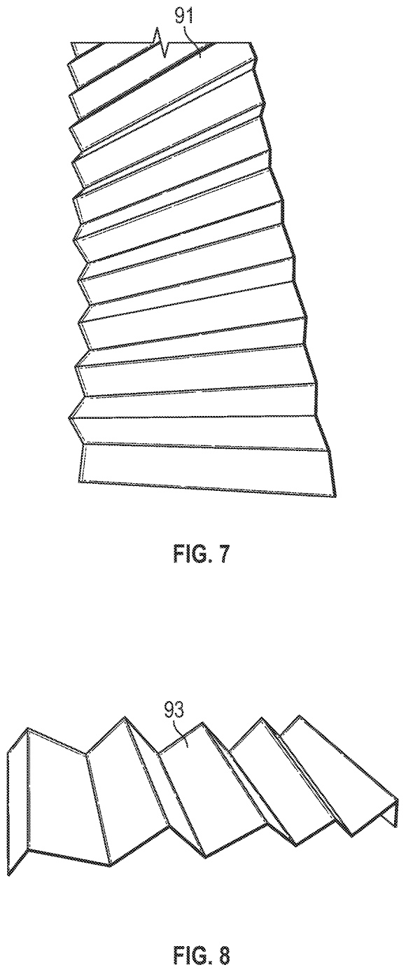

The separation films can optionally be pleated. FIG. 7 is a perspective view of a machine pleated structure 91 for a separation film. Machine pleating can be performed using, for example, a blade pleater or a push bar pleater. FIG. 8 is a perspective view of a hand pleated structure 93 for a separation film. Hand pleating can be performed with or without scoring. Both the blade pleating and hand pleating were shown to provide adequate pleats to an 8 mil film. The film represented in FIG. 7 was made with a 1.6 inch pleat height, and the blade pleater machine was able to impart a permanent crease in the film. The film represented in FIG. 8 was hand pleated with a pleat height of about 4 inches, and the crease was created by folding the film and pressing the fold flat onto a hard surface. Pleating can optionally be performed on other films, if the film structure and thickness is sufficient to adequately maintain pleats in the film.

Separation films can also be implemented with polymeric films engineered to shrink upon heating to tension the film. Heat shrink films can be made from a number of different polymers including polypropylene, polyethylene, and Polyvinyl Chloride (PVC). The films can be made in different ways that involve stretching and cross linking, or quenching, to lock in structure that then reverses upon heating. This heat shrink method could prove useful for making taut film structures.

A separation film structure can be made to function as a retractable, self-supporting roof. With data centers there is a desire to provide a hot aisle and a cold aisle, and separate those two aisles with walls made of separation films. There are also some designs that desire to make a roof to trap air, prevent air rise, and direct air. This roof, however, needs to comply with fire codes. One way to accomplish this compliance is by having a retractable roof so that in the case of a fire the roof will automatically retract to enable the fire suppression system to cover the area below. These roofs typically need to be able to span the width of the aisle.

This type of retractable roof could be made in several ways using the separation films described herein. The films could be pleated so that they can expand and contract with an appropriate track mechanism. The film pleat geometry can be chosen to provide the mechanical integrity required depending on the free span. Guide wires or strings can be placed through holes in the pleats to aide in the opening and closing. Flat film could also be rolled and unrolled if using an appropriate support and mechanism. This may require additional supports as the film itself may not be able to span the gap without drooping or sagging. The roller mechanism could work similar to a roller blind where with a slight pull it will retract or it could always be under tension to roll up and have an automatic release when a fire is detected. Finally, it could also mechanically roll and unroll with a motorized mechanism. Separation films can be textured rather than smooth to facilitate easier winding without telescoping.

Folded edges can be used for a better seal combined with a reclosable fastener for lower containment sealing to server for data center implementations. One example of how a film can be attached to a server is by putting an ninety degree bend in the film to provide more surface area for the film to then be attached to the outside of the server rack (e.g., on two opposing sides) using any of the fastening solutions described herein (e.g., mechanical, tape, adhesive, hook and loop, dual lock, or magnets).

The following are exemplary implementations of a separation film.
1. An oriented PET film from 3M Company. These 3-14 mil polyester films have a significantly lower CO2 footprint than the polycarbonate currently used in data centers. These PET films are typically offered at different caliper, for example 7 mils, 10 mils, and 14 mils.
2. The Safety and Security Window Film Safety Series from 3M Company. These films provide puncture and tear resistance and are typically adhered to glass to prevent it from shattering and making it more difficult for a person to break the glass. When used without the adhesive (and not on glass), these films can function as separation films.
3. A film with a sound absorbing feature to minimize vibration such as vibration damping tape from 3M Company.
4. Laminated films, such as a laminated film for film toughness and tear resistance, or a stripe laminated film for air encapsulation for a thermal barrier.
5. The Automotive Window Film Crystalline Series from 3M Company. This film can be used without adhesive and made thicker to function as a separation film.

### Other Uses for Separation Films

The separation films and fasteners for them described herein can also be used in other structures or facilities, aside from data centers, such as clean rooms, temporary structures for construction or remediation sites, and greenhouses.

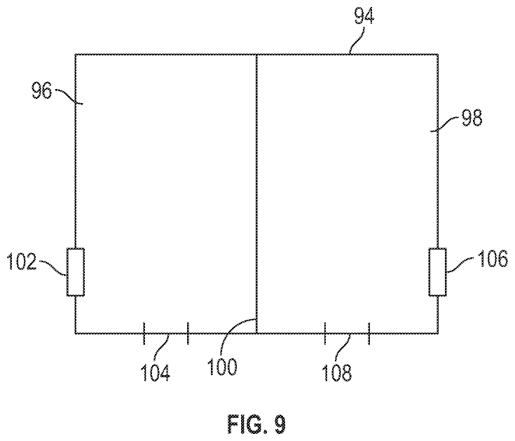

FIG. 9 is a top view diagram, looking down at a building or other structure 94, to illustrate use of a separation film in other buildings or structures. Structure 94 include a separation film 100 to separate a first space or section 96 from a second space or section 98. Structure 94 can also include a window 102 and a door 104 in space 96, and a window 106 and a door 108 in space 98. Separation film 100 can be implemented with any of the separation films described herein or films consistent with them. Separation film 100 can be held within a frame with attachment mechanisms such as any of the frames and attachment mechanisms described herein or structures consistent with them. Separation film 100 held within a frame can create an air barrier between sections 96 and 98 in order to isolate those sections from one another. In particular, the air barrier created by separation film 100 can prevent or hinder air flow from one section to another.

Clean rooms can benefit from the long continuous sections of separation films that can minimize seams and leaks. If structure 94 is a clean room, for example, separation film 100 can divide sections 96 and 98 to maintain one or both of them as a clean environment. Clean rooms can also benefit from optical transparency for window sections (e.g., windows 102 and 106) and door sections (e.g., doors 104 and 108) for safety and observation from inside and outside. Reclosable or replaceable sections could be advantageous so that contaminated or worn-out sections could be quickly and easily replaced.

For remediation and construction sites temporary enclosures are often needed, for example when doing mold or asbestos removal to contain air born contaminants. If structure 94 is a temporary enclosure, for example, separation film 100 can separate sections 96 and 98 for remediation or construction tasks. Some of these enclosures are single use and often made from thin plastic sheeting that is taped into position over wood or aluminum structures. However, other times reusable panels or pre-made panels for use as doors and entry points can be advantageous because they can be used multiple times and easily reconfigured from one remediation or construction site to another. Reusable film, such as the separation films described herein, could significantly reduce waste and likely be more cost effective in the long term or remediation and construction sites.

Greenhouses require a significant amount of film with high light transmission and UV stability. If structure 94 is a greenhouse, for example, separation film 100 can divide sections 96 and 98 in the greenhouse. Separation films and fasteners for them can be useful as replacement panels for windows (e.g., windows 102 and 106) and doors (e.g., doors 104 and 108) or other sections of the greenhouse. Film properties could be tailored to maximize light transmission to promote faster growth of plants in the greenhouse. These separation films could be made from recycled resin from either post-consumer or post-industrial sources.

1. A film module for use in a data center or other facility, comprising:
a frame;
a first portion of the frame having a transparent film; and
a second portion of the frame having an open space,
wherein the first portion is configured to separate a hot aisle from a cold aisle in a data center or other facility, and the second portion is configured to provide cold air from the cold aisle through electronic equipment to be cooled in the data center or other facility.

2. The film module of claim 1, wherein the first portion includes panels of the film.

3. The film module of claim 1, wherein the film is secured to the frame with fasteners.

4. The film module of claim 3, wherein the fasteners comprise a two-sided adhesive.

5. The film module of claim 3, wherein the fasteners comprise edge clips inserted into slots in the frame.

6. The film module of claim 3, wherein the fasteners comprise reclosable fasteners.

7. The film module of claim 6, wherein the reclosable fasteners comprise a tape.

8. The film module of claim 6, wherein the reclosable fasteners comprise hook and loop fasteners.

9. The film module of claim 3, wherein the fasteners comprise a round gasket.

10. The film module of claim 3, wherein the fasteners comprise a round gasket with a cover plate.

11. The film module of claim 3, wherein the fasteners comprise a cover plate with a ridge.

12. The film module of claim 1, wherein the frame includes two opposing sides, and at least a portion of the opposing sides include the film.

13. The film module of claim 1, wherein the film has a honeycomb structure.

14. The film module of claim 1, wherein the film has a corrugated structure.

15. The film module of claim 1, wherein the film has a thermoformed structure.

16. The film module of claim 1, wherein the film has a striped structure.

17-21. (canceled)

22. A data center or other facility configuration having a film module, comprising:
a hot aisle;
a cold aisle;
electronic equipment between the hot aisle and the cold aisle; and
a film module, comprising:
a frame;
a first portion of the frame having a transparent film; and
a second portion of the frame having an open space,
wherein the first portion is configured to separate the hot aisle from the cold aisle in the data center or other facility configuration, and the second portion is configured to provide cold air from the cold aisle through the electronic equipment to be cooled in the data center or other facility configuration and into the hot aisle.

23. The data center or other facility of claim 22, wherein the film is secured to the frame with fasteners.

24-25. (canceled)

26. A film module for use in a facility, comprising:
a frame; and
a transparent flexible film held within the frame between a first section and a second section within the facility,
wherein the separation film held within the frame creates an air barrier between the first section and the second section in order to prevent or hinder air flow between the first section and the second section.

27-29. (canceled)

30. The film module of claim 26, wherein the film is secured to the frame with fasteners.

31-32. (canceled)
